(19) United States
(12) Patent Application Publication
(10) Pub. No.: US 2024/0322039 A1
(43) Pub. Date: Sep. 26, 2024

(54) INTEGRATED CIRCUIT DEVICES

(71) Applicant: Samsung Electronics Co., Ltd., Suwon-si (KR)

(72) Inventors: Hyojin Kim, Suwon-si (KR); Jinbum Kim, Suwon-si (KR); Sangmoon Lee, Suwon-si (KR); Yongjun Nam, Suwon-si (KR); Ingeon Hwang, Suwon-si (KR)

(21) Appl. No.: 18/421,001

(22) Filed: Jan. 24, 2024

(30) Foreign Application Priority Data
Mar. 24, 2023 (KR) 10-2023-0038952
Mar. 27, 2023 (KR) 10-2023-0039917

(51) Int. Cl. H01L 29/78; H01L 29/423; H01L 29/66; H01L 29/775; H01L 29/786

(52) U.S. Cl. CPC H01L 29/7848; H01L 29/66439; H01L 29/66742; H01L 29/775; H01L 29/78696; H01L 29/42392

(57) ABSTRACT

The integrated circuit device includes a fin-type active region extending in a first direction, a channel region on the fin-type active region, a gate line on the channel region and extending in a second direction, and a source/drain region on the fin-type active region and in contact with the channel region, wherein the source/drain region includes a plurality of semiconductor layers including a first semiconductor layer that includes a portion in contact with the channel region and a portion in contact with the fin-type active region, a second semiconductor layer on the first semiconductor layer, and a third semiconductor layer on the second semiconductor layer, a germanium (Ge) content ratio in the first semiconductor layer is greater than or equal to 10 at % and less than 100 at %, and the Ge content ratio in the first semiconductor layer decreases towards a boundary with the second semiconductor layer.

### CROSS-REFERENCE TO RELATED APPLICATION(S)

This application is based on and claims priority under 35 U.S.C. § 119 to Korean Patent Application Nos. 10-2023-0038952, filed on Mar. 24, 2023, and 10-2023-0039917, filed on Mar. 27, 2023, in the Korean Intellectual Property Office, the disclosures of which are incorporated by reference herein in their entireties.

### BACKGROUND

The inventive concepts relate to integrated circuit devices, and more particularly, to integrated circuit devices including a field-effect transistor.

Along with the rapid progress of down-scaling of integrated circuit devices, there is a need to ensure not only a fast operating speed but also the operational accuracy in an integrated circuit device. In addition, as the integration of integrated circuit devices increases and the sizes thereof are reduced, the possibility that a process fault occurs in a manufacturing process of a nanosheet field-effect transistor may increase. Accordingly, there is a need to develop an integrated circuit device having a new structure capable of removing the possibility that a process fault occurs and to improve the performance and reliability of a nanosheet field-effect transistor.

### SUMMARY

The inventive concepts provide integrated circuit devices capable of providing stable performance and improved reliability of a nanosheet field-effect transistor.

According to aspects of the inventive concepts, there is provided an integrated circuit device. The integrated circuit device includes a fin-type active region extending on a substrate in a first horizontal direction, a channel region on the fin-type active region, a gate line at least partially surrounding the channel region on the fin-type active region and extending in a second horizontal direction that intersects with the first horizontal direction, and a source/drain region on the fin-type active region at a location adjacent to the gate line and in contact with the channel region, wherein the source/drain region includes a plurality of semiconductor layers, the plurality of semiconductor layers including a first semiconductor layer that includes a portion in contact with the channel region and a portion in contact with the fin-type active region, a second semiconductor layer on the first semiconductor layer, and a third semiconductor layer on the second semiconductor layer, wherein a germanium (Ge) content ratio in the first semiconductor layer is greater than or equal to 10 at % and less than 100 at %, and the Ge content ratio in the first semiconductor layer decreases towards a boundary with the second semiconductor layer.

According to aspects of the inventive concepts, there is provided an integrated circuit device. The integrated circuit device includes a fin-type active region extending on a substrate in a first horizontal direction, a nanosheet facing a fin top of the fin-type active region at a location separated from the fin top of the fin-type active region, a gate line at least partially surrounding the nanosheet on the fin-type active region and extending longitudinally in a second horizontal direction that intersects with the first horizontal direction, and a source/drain region facing the nanosheet in the first horizontal direction, wherein the source/drain region includes a plurality of semiconductor layers, the plurality of semiconductor layers including a first semiconductor layer that includes a portion in contact with the nanosheet and a portion in contact with the fin-type active region, a second semiconductor layer on the first semiconductor layer, and a third semiconductor layer on the second semiconductor layer, wherein a germanium (Ge) content ratio in the first semiconductor layer is greater than or equal to 10 at % and less than 100 at %, wherein the Ge content ratio in the first semiconductor layer decreases towards a boundary with the second semiconductor layer, wherein the nanosheet includes a first portion adjacent to the gate line and a second portion separated from the gate line with the first portion therebetween, and a Ge content ratio in the first portion is greater than a Ge content ratio in the second portion.

According to aspects of the inventive concepts, there is provided an integrated circuit device. The integrated circuit device includes a fin-type active region extending on a substrate in a first horizontal direction, a plurality of nanosheets facing a fin top of the fin-type active region at respective locations that are separated from the fin top and having different respective distances from the fin top in a vertical direction, a gate line at least partially surrounding each of the plurality of nanosheets on the fin-type active region and extending longitudinally in a second horizontal direction that intersects with the first horizontal direction, and a source/drain region facing the plurality of nanosheets in the first horizontal direction, wherein the source/drain region includes a plurality of semiconductor layers, the plurality of semiconductor layers including a first semiconductor layer that includes a portion in contact with the plurality of nanosheets and a portion in contact with the fin-type active region, a second semiconductor layer on the first semiconductor layer, and a third semiconductor layer on the second semiconductor layer, wherein each of the first semiconductor layer, the second semiconductor layer, and the third semiconductor layer includes a silicon germanium (SiGe) layer doped with a p-type dopant, wherein a germanium (Ge) content ratio in the first semiconductor layer is greater than or equal to 10 at % and less than 100 at %, wherein the Ge content ratio in the first semiconductor layer decreases towards a boundary with the second semiconductor layer, wherein the gate line includes a sub-gate portion that overlaps the first semiconductor layer in the first horizontal direction and a main gate portion that does not overlap the first semiconductor layer in the first horizontal direction, and wherein the Ge content ratio in the first semiconductor layer increases towards the sub-gate portion.

### BRIEF DESCRIPTION OF THE DRAWINGS

Embodiments of the inventive concepts will be more clearly understood from the following detailed description taken in conjunction with the accompanying drawings in which:

FIG. 1 is a plan layout diagram of some components in an integrated circuit device according to some embodiments;

FIG. 2A is a cross-sectional view taken along line X1-X1 of FIG. 1;

FIG. 2B is a cross-sectional view taken along line Y1-Y1 of FIG. 1;

FIG. 3 is a magnified cross-sectional view of a region EX1 of FIG. 2A;

FIGS. 4, 5A, and 5B are graphs for describing an integrated circuit device according to some embodiments;

FIG. 6 is a magnified cross-sectional view of a region EX2 of FIG. 2A;

FIG. 7 is a graph for describing an integrated circuit device according to some embodiments;

FIG. 8 is a cross-sectional view for describing an integrated circuit device according to some embodiments; and

FIGS. 9 to 15, 16A, 16B, and 17 to 20 are cross-sectional views for describing a method of manufacturing an integrated circuit device, according to some embodiments.

### DETAILED DESCRIPTION

Hereinafter, example embodiments are described in detail with reference to the accompanying drawings. Like reference numerals in the drawings denote like elements, and thus their repetitive description is omitted.

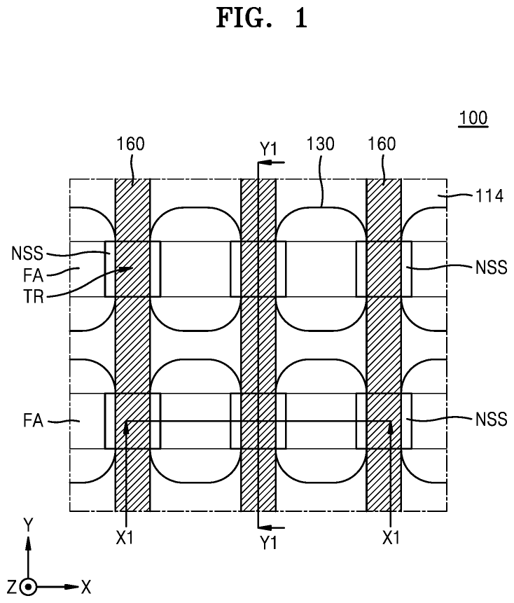

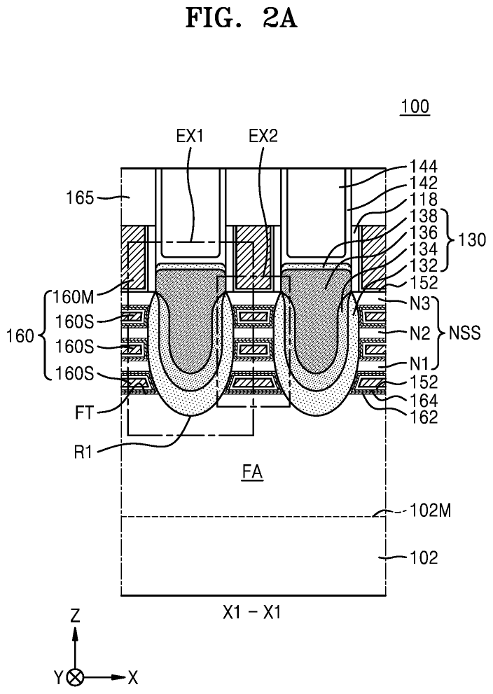

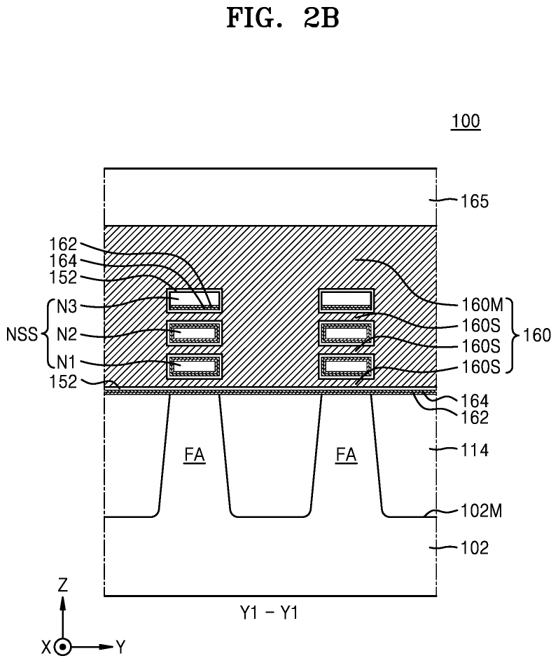

FIG. 1 is a plan layout diagram of some components in an integrated circuit device 100 according to some embodiments. FIG. 2A is a cross-sectional view taken along line X1-X1 of FIG. 1. FIG. 2B is a cross-sectional view taken along line Y1-Y1 of FIG. 1.

Hereinafter, the integrated circuit device 100 including a field-effect transistor TR having a gate-all-around structure that includes an active region in a nanowire or nanosheet shape and a gate surrounding the active region is described with reference to FIGS. 1, 2A, and 2B. It will be understood that “an element X surrounding an element Y” (or similar language) as used herein means that the element X is at least partially around the element Y but does not necessarily mean that the element X completely encloses the element Y.

The integrated circuit device 100 may include a plurality of fin-type active regions FA protruding upward from a substrate 102 in the vertical direction (Z direction) and extending longitudinally in a first horizontal direction (X direction) and a plurality of nanosheet stacks NSS above the plurality of fin-type active regions FA. As used herein, the term “longitudinally” indicates a longest dimension. As used herein, the term “nanosheet” indicates a conductive structure having a cross-section substantially perpendicular to a current flowing direction. The nanosheet may include a nanowire.

The substrate 102 may include a semiconductor, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). Each of the terms “SiGe”, “SiC”, “GaAs”, “InAs”, “InGaAs”, and “InP” used herein indicates a material including elements included in the term but is not a chemical formula indicating stoichiometric relationships of the elements.

A device isolation layer 114 covering both side walls of each of the plurality of fin-type active regions FA may be on the substrate 102. It will be understood that “an element X covers a surface of an element Y” (or similar language) means that the element X is on the surface of the element Y but does not necessarily mean that the element X covers the surface of the element Y entirely. The device isolation layer 114 may include an oxide layer, a nitride layer, or a combination thereof.

A plurality of gate lines 160 may be above the plurality of fin-type active regions FA. Each of the plurality of gate lines 160 may extend longitudinally in a second horizontal direction (Y direction) intersecting with the first horizontal direction (the X direction).

In regions in which the plurality of fin-type active regions FA intersect with the plurality of gate lines 160, the plurality of nanosheet stacks NSS may be above fin tops FT of the plurality of fin-type active regions FA, respectively. Each of the plurality of nanosheet stacks NSS may include at least one nanosheet facing a fin top FT of a fin-type active region FA at a location separated from the fin top FT in the vertical direction (the Z direction).

As shown in FIGS. 2A and 2B, each of the plurality of nanosheet stacks NSS may include a first nanosheet N1, a second nanosheet N2, and a third nanosheet N3 overlapping each other above a fin-type active region FA in the vertical direction (the Z direction). As used herein, “an element X overlaps an element Y in a direction Z” (or similar language) means that there is at least one line that extends in the direction Z and intersects both the elements X and Y. The first nanosheet N1, the second nanosheet N2, and the third nanosheet N3 may have different vertical distances (Z-directional distances) from the fin top FT of the fin-type active region FA. Although FIGS. 2A and 2B show that each of the plurality of nanosheet stacks NSS includes three nanosheets, the inventive concepts are not limited thereto and four or more or two or less nanosheets may be included.

Although FIG. 1 shows that the planar shape of a nanosheet stack NSS is approximately quadrangular, the nanosheet stack NSS is not limited thereto. The nanosheet stack NSS may have other planar shapes according to the planar shape of each of a fin-type active region FA and a gate line 160. The present disclosure discloses a feature where the plurality of nanosheet stacks NSS and the plurality of gate lines 160 are above one fin-type active region FA and the plurality of nanosheet stacks NSS are disposed in a line above one fin-type active region FA in the first horizontal direction (the X direction). However, the numbers of nanosheet stacks NSS and gate lines 160 above one fin-type active region FA are not particularly limited.

Each of the first nanosheet N1, the second nanosheet N2, and the third nanosheet N3 included in the nanosheet stack NSS may include a channel region. In the present disclosure, each of the first nanosheet N1, the second nanosheet N2, and the third nanosheet N3 may be referred to as a channel region. In some embodiments, each of the first nanosheet N1, the second nanosheet N2, and the third nanosheet N3 may have a thickness in a range of about 4 nm to about 6 nm but is not limited thereto. Herein, the thickness of each of the first nanosheet N1, the second nanosheet N2, and the third nanosheet N3 indicates a size thereof in the vertical direction (the Z direction). In some embodiments, the first nanosheet N1, the second nanosheet N2, and the third nanosheet N3 may have substantially the same thickness in the vertical direction (the Z direction). In some embodiments, at least some of the first nanosheet N1, the second nanosheet N2, and the third nanosheet N3 may have different thicknesses in the vertical direction (the Z direction).

In some embodiments, at least some of the first nanosheet N1, the second nanosheet N2, and the third nanosheet N3 included in one nanosheet stack NSS may have different sizes (e.g., may have different widths) in the first horizontal direction (the X direction). In some embodiments, at least some of the first nanosheet N1, the second nanosheet N2, and the third nanosheet N3 may have the same size (e.g., may have the same width) in the first horizontal direction (the X direction).

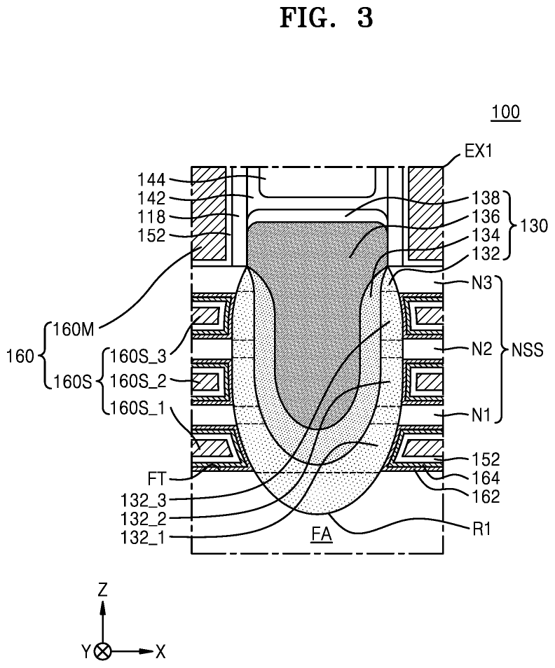

As shown in FIGS. 2A and 2B, each of the plurality of gate lines 160 may include a main gate portion 160M and a plurality of sub-gate portions 160S. The main gate portion 160M may cover an upper surface of a nanosheet stack NSS and may extend in the second horizontal direction (the Y direction). The plurality of sub-gate portions 160S may be integrally connected to the main gate portion 160M and may be disposed between the first nanosheet N1 and the second nanosheet N2, between the second nanosheet N2 and the third nanosheet N3, and between the first nanoshect N1 and a fin-type active region FA, respectively. In the vertical direction (the Z direction), the thickness of each of the plurality of sub-gate portions 160S may be less than the thickness of the main gate portion 160M. Although the present disclosure discloses in FIG. 3 that the plurality of sub-gate portions 160S respectively include a first sub-gate portion 160S_1, a second sub-gate portion 160S_2, and a third sub-gate portion 160S_3, the number of sub-gate portions 160S is not limited thereto.

Each of the plurality of gate lines 160 may include a metal, metal nitride, metal carbide, or a combination thereof. The metal may be selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from among titanium nitride (TiN) and tantalum nitride (TaN). The metal carbide may include titanium aluminum carbide (TiAIC). However, a material included in the plurality of gate lines 160 is not limited thereto.

A gate dielectric layer 152 may be between a nanosheet stack NSS and a gate line 160. In some embodiments, the gate dielectric layer 152 may include a stacked structure of an interface dielectric layer and a high-k layer. The interface dielectric layer may include a low-k material layer having a dielectric constant of 9 or less, e.g., a silicon oxide (SiO) layer, a silicon oxynitride (SiON) layer, or a combination thereof. In some embodiments, the interface dielectric layer may be omitted. The high-k layer may include a material having a dielectric constant greater than that of a SiO layer. For example, the high-k layer may have a dielectric constant of about 10 to about 25. The high-k layer may include hafnium oxide but is not limited thereto.

In some embodiments, a germanium (Ge) layer 162 and a silicon capping layer 164 may be further between the gate dielectric layer 152 and the nanosheet stack NSS.

Particularly, the silicon capping layer 164 surrounding a sub-gate portion 160S may be between the gate dielectric layer 152 and the nanosheet stack NSS. The silicon capping layer 164 may be on the gate dielectric layer 152 and separated from the sub-gate portion 160S with the gate dielectric layer 152 therebetween. The silicon capping layer 164 may include Si and have a thickness in a range of about 0.5 nm to about 1 nm.

Particularly, the Ge layer 162 surrounding the sub-gate portion 160S may be between the gate dielectric layer 152 and the nanosheet stack NSS. The Ge layer 162 may be on the gate dielectric layer 152 and the silicon capping layer 164 and separated from the sub-gate portion 160S with the gate dielectric layer 152 and the silicon capping layer 164 therebetween. The Ge layer 162 may be separated from the gate dielectric layer 152 with the silicon capping layer 164 therebetween. The Ge layer 162 may be a pure Ge layer, i.e., a layer having a Ge content ratio of 100 atomic percent (at %). The thickness of the Ge layer 162 may be 1 nm or less.

As shown in FIG. 2A, on a fin-type active region FA, a pair of source/drain regions 130 may be at both sides (e.g., opposing sides) of a gate line 160, i.e., with the gate line 160 therebetween. Between a pair of adjacent nanosheet stacks NSS, a source/drain region 130 may be on a fin-type active region FA. The source/drain region 130 may be in contact with a sidewall of a nanosheet stack NSS surrounded by an adjacent gate line 160.

Both sidewalls of each of the plurality of gate lines 160 may be covered by an outer insulating spacer 118. On an upper surface of each of the plurality of nanosheet stacks NSS, the outer insulating spacer 118 may cover both sidewalls of a main gate portion 160M. The outer insulating spacer 118 may be separated from a gate line 160 with a gate dielectric layer 152 therebetween. The outer insulating spacer 118 may include silicon nitride (SiN), SiO, silicon carbonitride (SiCN), silicon boron nitride (SiBN), SiON, silicon oxycarbonitride (SiOCN), silicon boron carbonitride (SiBCN), silicon oxycarbide (SiOC), or a combination thereof. Each of the terms “SiCN”, “SiBN”, “SION”, “SiOCN”, “SiBCN”, and “SiOC” used herein indicates a material including elements included in the term but is not a chemical formula indicating stoichiometric relationships of the elements.

As shown in FIGS. 2A and 2B, each of a plurality of source/drain regions 130 may include a portion overlapping the outer insulating spacer 118 in the vertical direction (the Z direction). For example, the first horizontal directional (X direction) width of a portion of each of the plurality of source/drain regions 130 overlapping the outer insulating spacer 118 in the vertical direction (the Z direction) may be within a range of about 0 nm to about 4 nm. In some embodiments, each of the plurality of source/drain regions 130 may not include a portion overlapping a main gate portion 160M in the vertical direction (the Z direction).

Both sidewalls (e.g., opposing sidewalls) of each of the plurality of sub-gate portions 160S may be separated from a source/drain region 130 with a gate dielectric layer 152 therebetween. The gate dielectric layer 152 may include a portion in contact with a first semiconductor layer 132 of a source/drain region 130.

As shown in FIG. 2A, a plurality of recesses R1 may be formed in a fin-type active region FA. A vertical level of the bottom surface of each of the plurality of recesses R1 may be lower than a vertical level of a fin top FT of the fin-type active region FA. The term “vertical level” used herein indicates a distance from a main surface 102M of the substrate 102 in the vertical direction (the Z direction).

As shown in FIG. 2A, the plurality of source/drain regions 130 may be in the plurality of recesses R1, respectively. Each of the plurality of source/drain regions 130 may be at a location adjacent to at least one gate line 160 selected from among the plurality of gate lines 160. Each of the plurality of source/drain regions 130 may have a sidewall facing the first nanosheet N1, the second nanosheet N2, and the third nanosheet N3 included in an adjacent nanosheet stack NSS. Each of the plurality of source/drain regions 130 may be in contact with the first nanosheet N1, the second nanosheet N2, and the third nanosheet N3 included in the adjacent nanosheet stack NSS. The plurality of source/drain regions 130 may have lower surfaces in contact with the plurality of fin-type active regions FA.

In some embodiments, as shown in FIGS. 2A and 2B, an upper surface of each of the gate dielectric layer 152, the gate line 160, and the outer insulating spacer 118 may be covered by a capping insulating pattern 165. The capping insulating pattern 165 may include a SiN layer.

A plurality of outer insulating spacers 118 and the plurality of source/drain regions 130 may be covered by an insulating liner 142. The insulating liner 142 may include SiN, SiO, SiCN, SiBN, SION, SiOCN, SiBCN, SiOC, or a combination thereof. In some embodiments, the insulating liner 142 may be omitted. An inter-gate insulating layer 144 may be on the insulating liner 142. The inter-gate insulating layer 144 may include a SiN layer, a SiO layer, SiON, SiOCN, or a combination thereof. When the insulating liner 142 is omitted, the inter-gate insulating layer 144 may be in contact with the plurality of source/drain regions 130.

Each of the plurality of source/drain regions 130 may include a plurality of semiconductor layers. The plurality of semiconductor layers may include the first semiconductor layer 132, a second semiconductor layer 134 on the first semiconductor layer 132, and a third semiconductor layer 136 on the second semiconductor layer 134. In some embodiments, the plurality of semiconductor layers may further include a capping layer 138 on the third semiconductor layer 136.

As shown in FIG. 1, a plurality of field-effect transistors TR may be formed on the substrate 102 at portions where the plurality of fin-type active regions FA intersect with the plurality of gate lines 160. The plurality of field-effect transistors TR may constitute a logic circuit or a memory device.

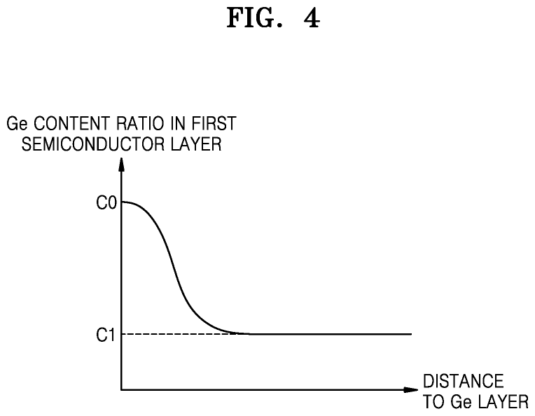

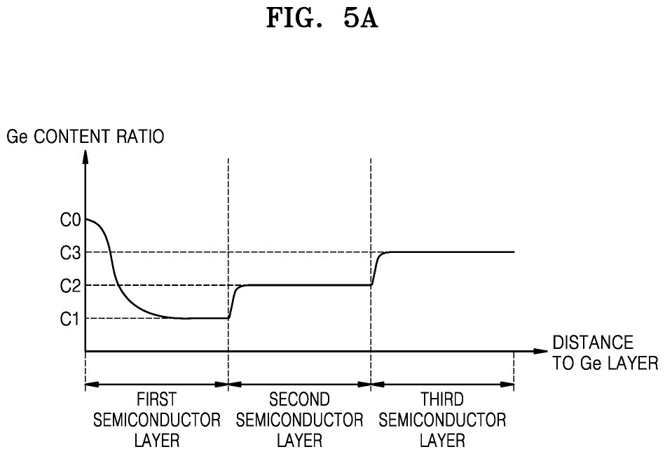

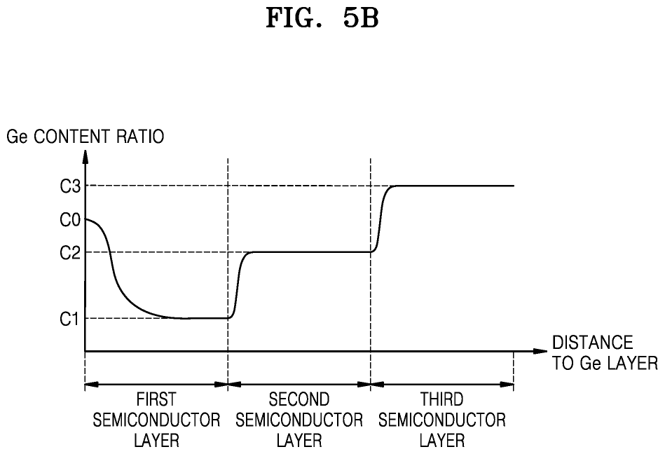

FIG. 3 is a magnified cross-sectional view of a region EX1 of FIG. 2A. FIGS. 4, 5A, and 5B are graphs for describing an integrated circuit device according to some embodiments. Particularly, FIG. 3 is a magnified cross-sectional view of a region including a source/drain region 130. Particularly, FIGS. 4, 5A, and 5B are graphs for describing a Ge content ratio inside the plurality of semiconductor layers of the source/drain region 130.

Referring to FIG. 3, as described above, the source/drain region 130 may include the plurality of semiconductor layers, and the plurality of semiconductor layers may include the first semiconductor layer 132, the second semiconductor layer 134, and the third semiconductor layer 136 sequentially disposed in the source/drain region 130.

In the source/drain region 130, the first semiconductor layer 132 may include a portion in contact with a channel region and a portion in contact with a fin-type active region FA. That is, the first semiconductor layer 132 may include a portion in contact with the first nanosheet N1, the second nanosheet N2, and the third nanosheet N3 and a portion in contact with the fin-type active region FA. The first semiconductor layer 132 may include a portion adjacent to the plurality of sub-gate portions 160S. In other words, the first semiconductor layer 132 may overlap the plurality of sub-gate portions 160S in the first horizontal direction (the X direction). For example, the first semiconductor layer 132 may not overlap the main gate portion 160M in the first horizontal direction (the X direction).

In the source/drain region 130, each of the first semiconductor layer 132, the second semiconductor layer 134, and the third semiconductor layer 136 may include a silicon germanium (Si₁₋ₓGeₓ) layer doped with a p-type dopant (herein, x≠0).

In some embodiments, the p-type dopant included in the source/drain region 130 may include boron (B), gallium (Ga), carbon (C), or a combination thereof but is not limited thereto.

The capping layer 138 may include an undoped Si layer, a Si layer doped with a p-type dopant, or a SiGe layer having a Ge content ratio less than that in the third semiconductor layer 136. In some embodiments, the capping layer 138 may not include a Ge element. For example, the capping layer 138 may include an undoped Si layer. In some embodiments, the capping layer 138 may include a Si layer doped with a boron (B) element or a SiGe layer doped with a B element. In some embodiments, the capping layer 138 may be omitted.

Referring to FIGS. 3 and 4, a Ge content ratio in the first semiconductor layer 132 may decrease as a distance to the Ge layer 162 surrounding the sub-gate portion 160S increases. Particularly, a Ge content ratio in a portion of the first semiconductor layer 132 overlapping the Ge layer 162 in the first horizontal direction (the X direction) may decrease away from the Ge layer 162 in the first horizontal direction (the X direction). For example, a Ge content ratio in a portion of the first semiconductor layer 132 overlapping the Ge layer 162 in the first horizontal direction (the X direction) may decrease as a distance from the Ge layer 162 in the first horizontal direction (the X direction) increases.

In some embodiments, the Ge content ratio in the first semiconductor layer 132 may decrease as a distance to the sub-gate portion 160S increases. Particularly, a Ge content ratio in a portion of the first semiconductor layer 132 overlapping the sub-gate portion 160S in the first horizontal direction (the X direction) may decrease away from the sub-gate portion 160S in the first horizontal direction (the X direction). For example, a Ge content ratio in a portion of the first semiconductor layer 132 overlapping the sub-gate portion 160S in the first horizontal direction (the X direction) may decrease as a distance from the sub-gate portion 160S in the first horizontal direction (the X direction) increases.

For example, the first semiconductor layer 132 may include a plurality of sub-portions, e.g., first, second, and third sub-portions 132_1, 132_2, and 132_3, each overlapping the plurality of sub-gate portions 160S in the first horizontal direction (the X direction), and a Ge content ratio in the first, second, and third sub-portions 132_1, 132_2, and 132_3 may decrease as a distance to the each of the plurality of sub-gate portions 160S in the first horizontal direction (the X direction) increases. For example, the first sub-portion 132_1 may overlap the first sub-gate portion 160S_1 in the first horizontal direction (the X direction), and a Ge content ratio in the first sub-portion 132_1 may decrease away from the first sub-gate portion 160S_1 in the first horizontal direction (the X direction). For example, the second sub-portion 132_2 may overlap the second sub-gate portion 160S_2 in the first horizontal direction (the X direction), and a Ge content ratio in the second sub-portion 132_2 may decrease away from the second sub-gate portion 160S_2 in the first horizontal direction (the X direction). For example, the third sub-portion 132_3 may overlap the third sub-gate portion 160S_3 in the first horizontal direction (the X direction), and a Ge content ratio in the third sub-portion 132_3 may decrease away from the third sub-gate portion 160S_3 in the first horizontal direction (the X direction). However, the Ge content ratios in the first, second, and third sub-portions 132_1, 132_2, and 132_3 may differ from each other even though respective distances to the plurality of sub-gate portions 160S are identical to each other. In FIG. 3, the first, second, and third sub-portions 132_1, 132_2, and 132_3 are illustratively shown for convenience of description and may include a portion not overlapping the plurality of sub-gate portions 160S.

In some embodiments, the Ge content ratio in the first semiconductor layer 132 may decrease towards the boundary with the second semiconductor layer 134. For example, the Ge content ratio in the first semiconductor layer 132 may have the maximum value at the maximum distance to the second semiconductor layer 134, e.g., at the boundary with a recess R1, and may have the minimum value at the boundary with the second semiconductor layer 134.

In some embodiments, the Ge content ratio in the first semiconductor layer 132 may be greater than or equal to 10 at % and less than 100 at %. That is, the Ge content ratio in the first semiconductor layer 132 may decrease within a range greater than or equal to 10 at % and less than 100 at % as a distance to the sub-gate portion 160S increases. That is, the Ge content ratio in the first semiconductor layer 132 may decrease within the range greater than or equal to 10 at % and less than 100 at % as a distance to the channel region increases. That is, the Ge content ratio in the first semiconductor layer 132 may decrease within the range greater than or equal to 10 at % and less than 100 at % towards the boundary with the second semiconductor layer 134.

Particularly, the Ge content ratio in the first semiconductor layer 132 may gradually decrease from a maximum content ratio C0 (see FIG. 4) less than 100 at % to a first content ratio C1 (see FIG. 4) greater than or equal to 10 at %. For example, a portion of the first semiconductor layer 132 overlapping the sub-gate portion 160S in the first horizontal direction (the X direction) may have the maximum content ratio C0 less than 100 at % when a distance to the sub-gate portion 160S is minimum and may have the first content ratio C1 greater than or equal to 10 at % when a distance to the sub-gate portion 160S is maximum. For example, a portion of the first semiconductor layer 132 overlapping the channel region in the first horizontal direction (the X direction) may have the maximum content ratio C0 less than 100 at % when a distance to the channel region is minimum and may have the first content ratio C1 greater than or equal to 10 at % when a distance to the channel region is maximum. For example, the first semiconductor layer 132 may have the maximum content ratio C0 less than 100 at % when a distance to the second semiconductor layer 134 is maximum and may have the first content ratio C1 greater than or equal to 10 at % at the boundary with the second semiconductor layer 134.

Referring to FIGS. 3, 5A, and 5B, the Ge content ratio in the first semiconductor layer 132 at the boundary with the second semiconductor layer 134 may be less than a Ge content ratio of the second semiconductor layer 134, and the Ge content ratio of the second semiconductor layer 134 may be less than a Ge content ratio of the third semiconductor layer 136.

Particularly, a Ge content ratio of the plurality of semiconductor layers may decrease in the first semiconductor layer 132, partially increase in the second semiconductor layer 134, and partially increase in the third semiconductor layer 136 as a distance to the Ge layer 162 surrounding the sub-gate portion 160S increases. For example, a Ge content ratio in the first semiconductor layer 132 may increase towards the sub-gate portion 160S.

For example, a portion of the plurality of semiconductor layers overlapping the channel region in the first horizontal direction (the X direction) may have the maximum content ratio C0 when a distance to the Ge layer 162 in the first horizontal direction (the X direction) is minimum, gradually decrease in the first semiconductor layer 132 away from the Ge layer 162 in the first horizontal direction (the X direction), and may have the first content ratio C1 when a distance to the Ge layer 162 in the first horizontal direction (the X direction) is maximum. That is, a portion of the plurality of semiconductor layers overlapping the Ge layer 162 in the first horizontal direction (the X direction) may have the first content ratio C1 at the boundary with the second semiconductor layer 134, may have a second content ratio C2 in the second semiconductor layer 134, and may have a third content ratio C3 in the third semiconductor layer 136, and the second content ratio C2 is greater than the first content ratio C1 and the third content ratio C3 is greater than the second content ratio C2.

Particularly, the Ge content ratio of the plurality of semiconductor layers may decrease in the first semiconductor layer 132, partially increase in the second semiconductor layer 134, and partially increase in the third semiconductor layer 136 as a distance to the sub-gate portion 160S increases. Particularly, a Ge content ratio in a portion of the plurality of semiconductor layers overlapping the sub-gate portion 160S in the first horizontal direction (the X direction) may decrease in the first semiconductor layer 132, partially increase in the second semiconductor layer 134, and partially increase in the third semiconductor layer 136 away from the sub-gate portion 160S in the first horizontal direction (the X direction).

For example, the portion of the plurality of semiconductor layers overlapping the sub-gate portion 160S in the first horizontal direction (the X direction) may have the maximum content ratio C0 when a distance to the sub-gate portion 160S in the first horizontal direction (the X direction) is minimum, gradually decrease in the first semiconductor layer 132 away from the sub-gate portion 160S in the first horizontal direction (the X direction), and may have the first content ratio C1 when a distance to the sub-gate portion 160S in the first horizontal direction (the X direction) is maximum. That is, the portion of the plurality of semiconductor layers overlapping the sub-gate portion 160S in the first horizontal direction (the X direction) may have the first content ratio C1 at the boundary with the second semiconductor layer 134, may have the second content ratio C2 in the second semiconductor layer 134, and may have the third content ratio C3 in the third semiconductor layer 136, and the second content ratio C2 is greater than the first content ratio C1 and the third content ratio C3 is greater than the second content ratio C2.

Particularly, the Ge content ratio of the plurality of semiconductor layers may decrease in the first semiconductor layer 132 towards the boundary with the second semiconductor layer 134, partially increase by passing through the boundary with the second semiconductor layer 134, and partially increase by passing through the boundary with the third semiconductor layer 136. For example, the Ge content ratio in the first semiconductor layer 132 may have the maximum content ratio C0 at the maximum distance to the second semiconductor layer 134, e.g., at the boundary with the recess R1, may have the first content ratio C1 at the boundary with the second semiconductor layer 134, increase up to the second content ratio C2 by passing through the boundary with the second semiconductor layer 134, and increase up to the third content ratio C3 by passing through the boundary with the third semiconductor layer 136.

In summary, the Ge content ratio in the plurality of semiconductor layers may decrease from the maximum content ratio C0 to the first content ratio C1 in the first semiconductor layer 132, increase to the second content ratio C2 in the second semiconductor layer 134, and increase to the third content ratio C3 in the third semiconductor layer 136, and the second content ratio C2 is greater than the first content ratio C1 and the third content ratio C3 is greater than the second content ratio C2. Herein, the first semiconductor layer 132 may have the first content ratio C1 that is the minimum content ratio at the boundary with the second semiconductor layer 134.

In some embodiments, the Ge content ratio in the plurality of semiconductor layers may be greater than or equal to 10 at % and less than 100 at %. That is, each of the maximum content ratio C0, the first content ratio C1, the second content ratio C2, and the third content ratio C3 of the plurality of semiconductor layers may be a Ge content ratio greater than or equal to 10 at % and less than 100 at %.

In some embodiments, the first semiconductor layer 132 may include a portion having a greater Ge content ratio than the second semiconductor layer 134 and/or the third semiconductor layer 136.

In some embodiments, as shown in FIG. 5A, each of the first content ratio C1, the second content ratio C2, and the third content ratio C3 may be less than the maximum content ratio C0 of the first semiconductor layer 132. That is, the maximum value of the Ge content ratio of the plurality of semiconductor layers may be the maximum content ratio C0 of the first semiconductor layer 132.

In some embodiments, as shown in FIG. 5B, the first content ratio C1 and the second content ratio C2 may be less than the maximum content ratio C0 of the first semiconductor layer 132, but the third content ratio C3 may be greater than the maximum content ratio C0 of the first semiconductor layer 132. That is, the maximum value of the Ge content ratio of the plurality of semiconductor layers may be the third content ratio C3 of the third semiconductor layer 136.

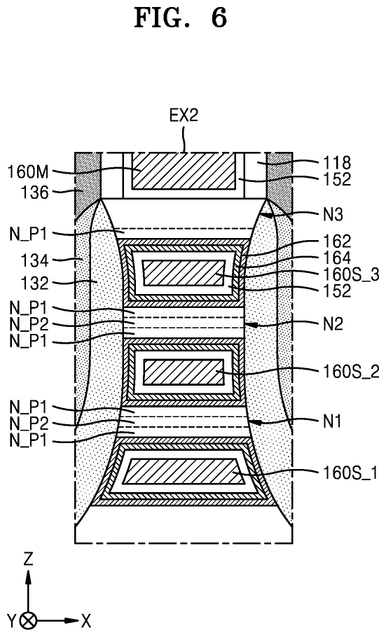

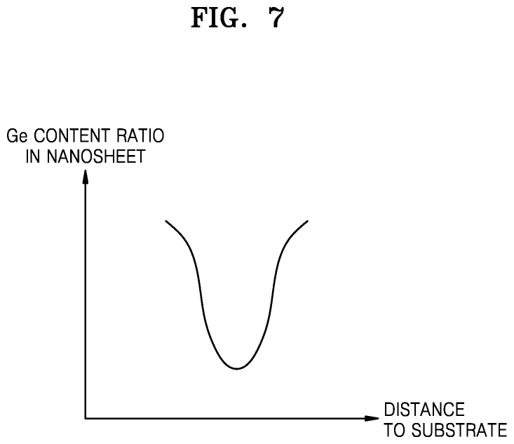

FIG. 6 is a magnified cross-sectional view of a region EX2 of FIG. 2A. FIG. 7 is a graph for describing an integrated circuit device according to some embodiments. Particularly, FIG. 6 is a magnified cross-sectional view of a channel region, e.g., a region including a nanosheet stack NSS. Particularly, FIG. 7 is a graph for describing a Ge content ratio in the channel region, e.g., the nanosheet stack NSS.

Referring to FIG. 6, as described above, the nanosheet stack NSS in contact with a side surface of a source/drain region 130 may be above a fin-type active region FA. The nanosheet stack NSS may include a plurality of nanosheets, e.g., the first nanosheet N1, the second nanosheet N2, and the third nanosheet N3.

In some embodiments, each of the first nanosheet N1, the second nanosheet N2, and the third nanosheet N3 may include a first portion N_P1 adjacent to a sub-gate portion 160S and a second portion N_P2 separated from the sub-gate portion 160S with the first portion N_P1 therebetween.

In some embodiments, the first portion N_P1 may be adjacent to the Ge layer 162 surrounding the sub-gate portion 160S. Particularly, the first portion N_P1 may be in contact with the Ge layer 162 surrounding the sub-gate portion 160S. In some embodiments, the second portion N_P2 may be separated from the Ge layer 162 with the first portion N_P1 therebetween.

In some embodiments, a Ge content ratio of the first portion N_P1 may be greater than a Ge content ratio of the second portion N_P2. That is, the Ge content ratio of the first portion N_P1 in contact with the Ge layer 162 may be greater than the Ge content ratio of the second portion N_P2 separated from the Ge layer 162.

In some embodiments, a Ge content ratio in the first nanosheet N1, the second nanosheet N2, and the third nanosheet N3 may increase towards the sub-gate portion 160S and decrease away from the sub-gate portion 160S. Particularly, the Ge content ratio in the first nanosheet N1, the second nanosheet N2, and the third nanosheet N3 may increase towards the Ge layer 162 and decrease away from the Ge layer 162.

Referring to FIGS. 6 and 7, for example, a Ge content ratio in the second nanosheet N2 may increase towards the third sub-gate portion 160S_3, decrease towards the substrate 102, i.e., away from the third sub-gate portion 160S_3, and increase towards the second sub-gate portion 160S_2 after passing through an intermediate point of the second nanosheet N2. For example, the Ge content ratio in the first nanosheet N1, the second nanosheet N2, and the third nanosheet N3 may increase towards the gate line 160. In other words, the Ge content ratio in the first nanosheet N1, the second nanosheet N2, and the third nanosheet N3 may increase towards the Ge layer 162 and decrease away from the Ge layer 162. That is, each of the first nanosheet N1, the second nanosheet N2, and the third nanosheet N3 may include a portion in which a Ge content ratio decreases and then increases.

Referring to FIGS. 1 to 7, in some embodiments, in the integrated circuit device 100, a pair of source/drain regions 130 (i.e., first and second source/drain regions 130), a gate line 160 between the pair of source/drain regions 130, and the channel region (e.g., a region including the nanosheet stack NSS having the first, second, and third nanosheets N1, N2, N3) between the pair of source/drain regions 130 may constitute a positive channel metal oxide semiconductor (PMOS) transistor.

The integrated circuit device 100 according to some embodiments of the inventive concepts may include the first semiconductor layer 132 having an increased Ge content ratio. Particularly, the integrated circuit device 100 according to some embodiments of the inventive concepts may include the first semiconductor layer 132 having a Ge content ratio of 10 at % to 100 at %. In some embodiments, because the integrated circuit device 100 according to the inventive concepts includes the first semiconductor layer 132 having an increased Ge content ratio, a stress boosting effect due to lattice mismatch in the first semiconductor layer 132 may increase. Accordingly, the mobility of carriers, e.g., electrons, in the channel region may increase, thereby decreasing a channel resistance. In other words, the integrated circuit device 100 including a transistor with a decreased channel resistance may be provided according to embodiments of the inventive concepts. In other words, the integrated circuit device 100 with improved performance and reliability may be provided according to embodiments of the inventive concepts.

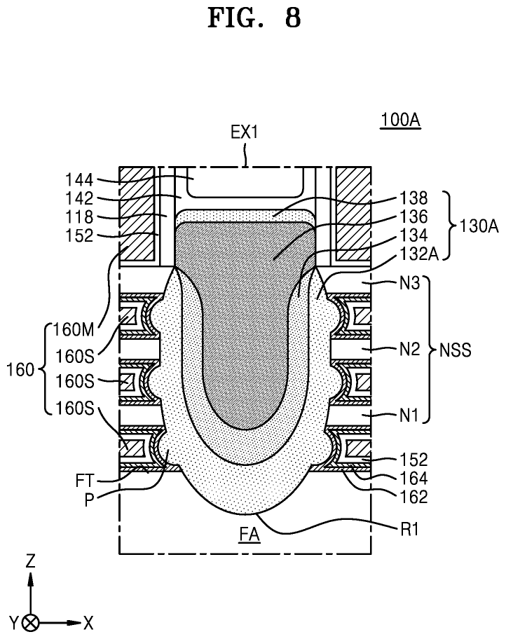

FIG. 8 is a cross-sectional view for describing an integrated circuit device 100A according to some embodiments.

Referring to FIG. 8, the integrated circuit device 100A has generally the same structure as the integrated circuit device 100 described with reference to FIGS. 1 to 7. The integrated circuit device 100A may include a source/drain region 130A filling a recess R1 in a fin-type active region FA.

The source/drain region 130A may have generally the same structure as the source/drain region 130 described with reference to FIGS. 1, 2A, 2B, 3, 4, 5A, and 5B. However, the source/drain region 130A may include a first semiconductor layer 132A having a plurality of protrusion portions P respectively protruding or extending toward the plurality of sub-gate portions 160S. In the source/drain region 130A, the first semiconductor layer 132A may include a portion in contact with the first nanosheet N1, the second nanosheet N2, and the third nanosheet N3 and a portion in contact with the fin-type active region FA. The second semiconductor layer 134 may be on the first semiconductor layer 132A. The third semiconductor layer 136 may be on the second semiconductor layer 134.

A more detailed structure of the first semiconductor layer 132A is similar to that of the first semiconductor layer 132 described with reference to FIGS. 3, 4, 5A, and 5B. That is, a Ge content ratio in the first semiconductor layer 132A may decrease as a distance to the sub-gate portion 160S increases. Particularly, a Ge content ratio in a portion of the first semiconductor layer 132A overlapping the sub-gate portion 160S in the first horizontal direction (the X direction) may decrease away from the sub-gate portion 160S in the first horizontal direction (the X direction). When the first semiconductor layer 132A includes a protrusion portion P, the protrusion portion P may be closer to the sub-gate portion 160S in the first horizontal direction (the X direction) than a portion of the first semiconductor layer 132A that is not the protrusion portion P. Therefore, the protrusion portion P may have a greater Ge content ratio than the portion of the first semiconductor layer 132A that is not the protrusion portion P.

In addition, the Ge content ratio in the first semiconductor layer 132A may decrease as a distance to the channel region increases, as a distance to the nanosheet stack NSS increases, and a distance to each of the first nanosheet N1, the second nanosheet N2, and the third nanosheet N3 increases. The protrusion portion P may be closer to the channel region, the nanosheet stack NSS, and/or each of the first nanosheet N1, the second nanosheet N2, and the third nanosheet N3 in the first horizontal direction (the X direction) than the portion of the first semiconductor layer 132A that is not the protrusion portion P. Therefore, the protrusion portion P may have a greater Ge content ratio than the portion of the first semiconductor layer 132A that is not the protrusion portion P.

In addition, in some embodiments, the Ge content ratio in the first semiconductor layer 132A may decrease towards the boundary with the second semiconductor layer 134. The protrusion portion P is farther from the boundary with the second semiconductor layer 134 than the portion of the first semiconductor layer 132A that is not the protrusion portion P, and thus the protrusion portion P may have a greater Ge content ratio than the portion of the first semiconductor layer 132A that is not the protrusion portion P.

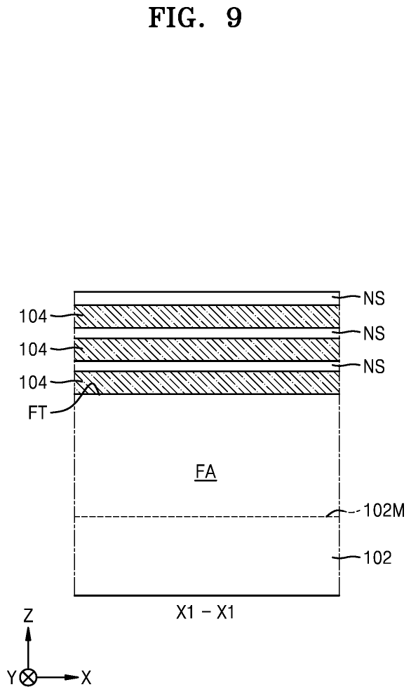

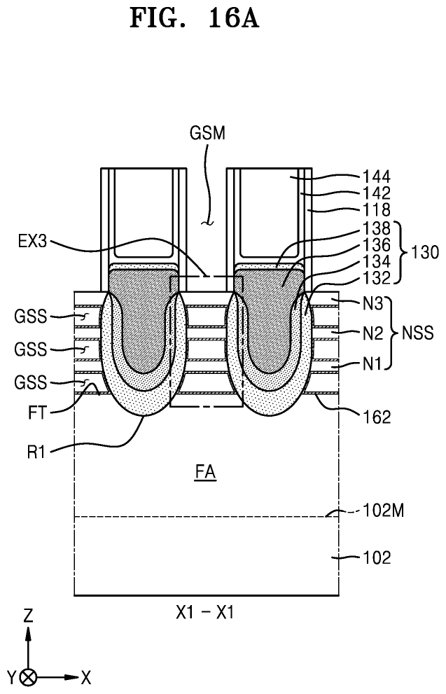

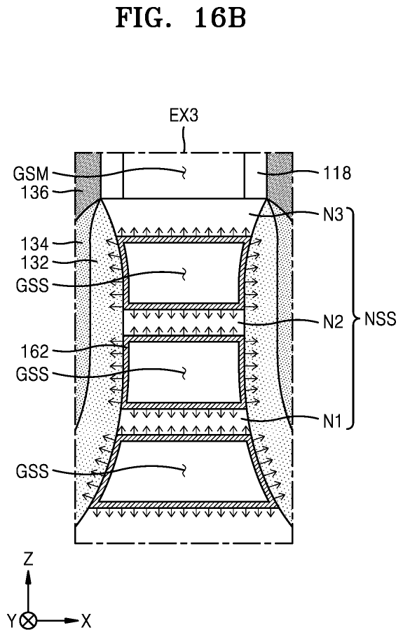

FIGS. 9 to 20 are cross-sectional views for describing a method of manufacturing the integrated circuit device 100, according to some embodiments. Particularly, FIGS. 9 to 15, 16A, and 17 to 20 are cross-sectional views corresponding to FIG. 2A to describe a method of manufacturing the integrated circuit device 100, and FIG. 16B is a magnified cross-sectional view of a region EX3 of FIG. 16A to describe an operation corresponding to FIG. 16A.

Referring to FIG. 9, a plurality of sacrificial semiconductor layers 104 and a plurality of nanosheet semiconductor layers NS may be alternately stacked one by one on the substrate 102, and then the plurality of fin-type active regions FA may be defined in the substrate 102 by etching portions of the plurality of sacrificial semiconductor layers 104, the plurality of nanosheet semiconductor layers NS, and the substrate 102. Thereafter, the device isolation layer 114 (see FIGS. 1 and 2B) covering a sidewall of each of the plurality of fin-type active regions FA may be formed. A stacked structure of the plurality of sacrificial semiconductor layers 104 and the plurality of nanosheet semiconductor layers NS may remain on the fin top FT of each of the plurality of fin-type active regions FA. In some embodiments, the thickness of each of the plurality of sacrificial semiconductor layers 104 may be greater than the thickness of each of the plurality of nanosheet semiconductor layers NS. In some embodiments, unlike that shown in FIG. 9, the thickness of each of the plurality of sacrificial semiconductor layers 104 may be the same as the thickness of each of the plurality of nanosheet semiconductor layers NS.

The plurality of sacrificial semiconductor layers 104 and the plurality of nanosheet semiconductor layers NS may include semiconductor materials having different etch selectivity. In some embodiments, the plurality of nanosheet semiconductor layers NS may include a Si layer and the plurality of sacrificial semiconductor layers 104 may include a SiGe layer. In some embodiments, a Ge content in the plurality of sacrificial semiconductor layers 104 may be constant. The SiGe layer constituting the plurality of sacrificial semiconductor layers 104 may have a constant Ge content selected within a range of about 5 at % to about 60 at %, e.g., about 10 at % to about 40 at %. The Ge content in the SiGe layer constituting the plurality of sacrificial semiconductor layers 104 may be variously selected according to circumstances.

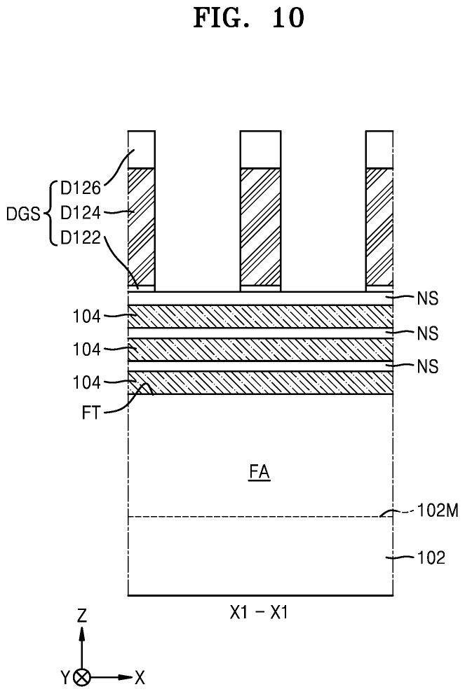

Referring to FIG. 10, a plurality of dummy gate structures DGS may be formed on the stacked structure of the plurality of sacrificial semiconductor layers 104 and the plurality of nanosheet semiconductor layers NS.

Each of the plurality of dummy gate structures DGS may be formed to extend longitudinally in the second horizontal direction (the Y direction). Each of the plurality of dummy gate structures DGS may have a structure in which an oxide layer D122, a dummy gate layer D124, and a capping layer D126 are sequentially stacked. In some embodiments, the dummy gate layer D124 may include polysilicon and the capping layer D126 may include a SiN layer.

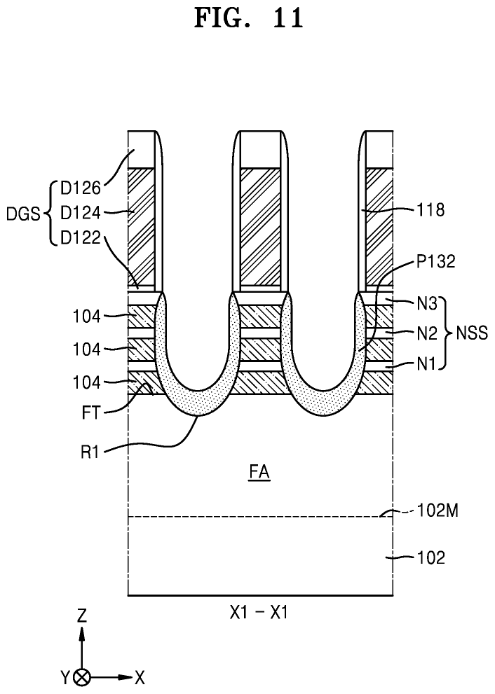

Referring to FIG. 11, the plurality of outer insulating spacers 118 covering both sidewalls of the plurality of dummy gate structures DGS may be formed, and then the plurality of dummy gate structures DGS and the plurality of outer insulating spacers 118 may be used as an etching mask to etch a portion of each of the plurality of sacrificial semiconductor layers 104 and the plurality of nanosheet semiconductor layers NS and a portion of the fin-type active region FA, thereby dividing the plurality of nanosheet semiconductor layers NS into the plurality of nanosheet stacks NSS and forming the plurality of recesses R1 in the fin-type active region FA. Each of the plurality of nanosheet stacks NSS may include the first nanosheet N1, the second nanosheet N2, and the third nanosheet N3. To form the plurality of recesses R1, etching using dry etching, wet etching, or a combination thereof may be performed.

Thereafter, a pre-first semiconductor layer P132 may be formed on the fin-type active region FA at both sides of each of the plurality of nanosheet stacks NSS (e.g., in the first recess R1).

In some embodiments, to form the pre-first semiconductor layer P132, a semiconductor material may be epitaxially grown from the surface of the fin-type active region FA exposed at the bottom surface of a recess R1, a sidewall of each of the first nanosheet N1, the second nanosheet N2, and the third nanosheet N3 included in the nanosheet stack NSS, and a sidewall of each of the plurality of sacrificial semiconductor layers 104.

In some embodiments, to form the pre-first semiconductor layer P132, a low-pressure chemical vapor deposition (LPCVD) process, a selective epitaxial growth (SEG) process, or a cyclic deposition and etching (CDE) process may be performed using raw materials including an element semiconductor precursor. The element semiconductor precursor may include a Si source, a Ge source, or the like.

In some embodiments, to form the pre-first semiconductor layer P132, a Si source and a Ge source may be used. Silane (SiH₄), disilane (Si₂H₆), trisilane (Si₃H₈), dichlorosilane (SiH₂Cl₂), or the like may be used as the Si source, but the Si source is not limited thereto. Germane (GeH₄), digermane (Ge₂H₆), trigermane (Ge₃H₈), tetragermane (Ge₄H₁₀), dichlorogermane (Ge₂H₂Cl₂), or the like may be used as the Ge source, but the Ge source is not limited thereto. When the first semiconductor layer 132 includes a SiGe layer doped with a boron (B) atom, diborane (B₂H₆), triborane, tetraborane, pentaborane, or the like may be used as a B source, but the B source is not limited thereto.

In some embodiments, to form the pre-first semiconductor layer P132, an epitaxial growth process may be performed under a temperature selected within a range of about 600° C. to about 620° C. but is not limited thereto.

In some embodiments, a Ge content ratio in the pre-first semiconductor layer P132 may be about 0 at % to about 10 at %. For example, the Ge content ratio in the pre-first semiconductor layer P132 may be less than 10 at %.

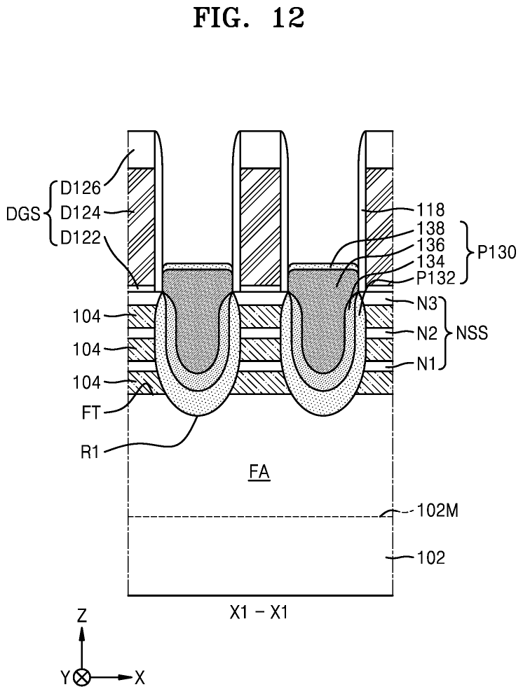

Referring to FIG. 12, the second semiconductor layer 134 may be formed on the pre-first semiconductor layer P132. Thereafter, the third semiconductor layer 136 and the capping layer 138 may be sequentially formed on the second semiconductor layer 134 to form a plurality of pre-source/drain regions P130.

In some embodiments, to form the second semiconductor layer 134 and the third semiconductor layer 136, the Si source, the Ge source, and the B source may be used. In some embodiments, Ge content ratios in the second semiconductor layer 134 and the third semiconductor layer 136 may be about 10 at % to about 100 at %. Particularly, the Ge content ratio in the second semiconductor layer 134 may be greater than the Ge content ratio in the pre-first semiconductor layer P132, and the Ge content ratio in the third semiconductor layer 136 may be greater than the Ge content ratio in the second semiconductor layer 134.

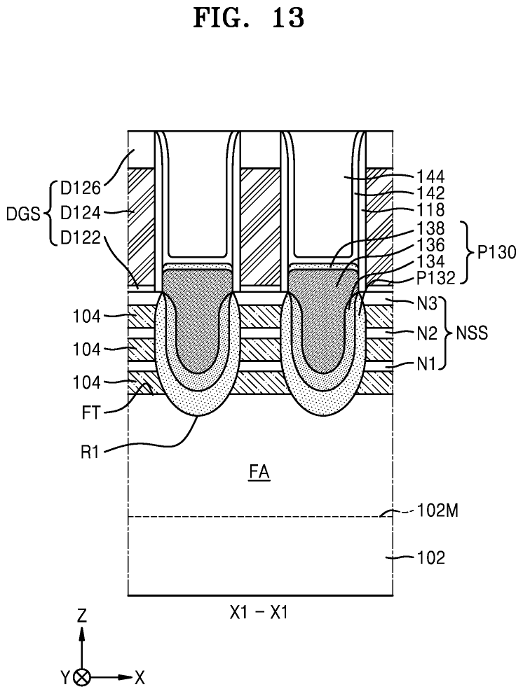

Referring to FIG. 13, the insulating liner 142 covering the result of FIG. 12 in which the plurality of pre-source/drain regions P130 are formed may be formed, the inter-gate insulating layer 144 may be formed on the insulating liner 142, and then the insulating liner 142 and the inter-gate insulating layer 144 may be planarized to expose an upper surface of the capping layer D126.

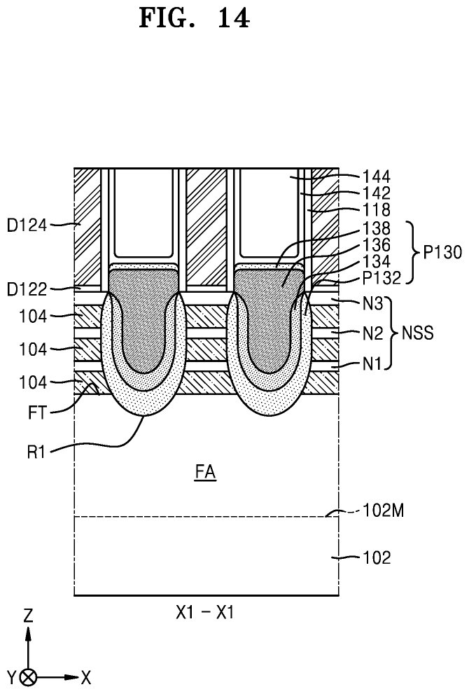

Referring to FIG. 14, the capping layer D126 may be removed from the result of FIG. 13 to expose an upper surface of the dummy gate layer D124, and portions of the insulating liner 142 and the inter-gate insulating layer 144 may be removed to make an upper surface of the inter-gate insulating layer 144 be approximately at the same level as the upper surface of the dummy gate layer D124.

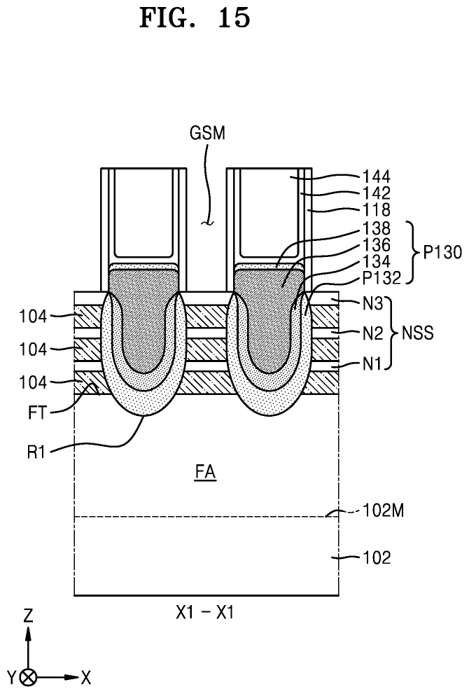

Referring to FIG. 15, the dummy gate layer D124 and the oxide layer D122 therebeneath may be removed from the result of FIG. 14 to prepare a main gate space GSM and expose the plurality of nanosheet stacks NSS through the main gate space GSM.

Referring to FIG. 16A, the plurality of sacrificial semiconductor layers 104 remaining on the fin-type active region FA may be removed from the result of FIG. 15 through the main gate space GSM to prepare a sub-gate space GSS between the third nanosheet N3 and the second nanosheet N2, between the second nanosheet N2 and the first nanosheet N1, and between the first nanosheet N1 and the fin top FT of the fin-type active region FA.

In some embodiments, to selectively remove the plurality of sacrificial semiconductor layers 104, the difference between the etching selectivity of the first nanosheet N1, the second nanosheet N2, and the third nanosheet N3 and the etching selectivity of the plurality of sacrificial semiconductor layers 104 may be used. To selectively remove the plurality of sacrificial semiconductor layers 104, a liquefied or gaseous etchant may be used. In some embodiments, to selectively remove the plurality of sacrificial semiconductor layers 104, an acetic acid (CH₃COOH)-based etchant, e.g., an etchant including a mixture of CH₃COOH, nitric acid (HNO₃), and hydrogen fluoride (HF) or an etchant including a mixture of CH₃COOH, hydrogen peroxide (H₂O₂), and HF, may be used, but the etchant is not limited thereto.

Thereafter, the Ge layer 162 covering an exposed surface of each of the first nanosheet N1, the second nanosheet N2, the third nanosheet N3, and the fin-type active region FA on each sub-gate space GSS may be formed. In some embodiments, to form the Ge layer 162, an epitaxial chemical vapor deposition (CVD) process may be performed. The thickness of the Ge layer 162 may be 1 nm or less.

Thereafter, a process of inducing Ge diffusion inside the pre-first semiconductor layer P132, the first nanosheet N1, the second nanosheet N2, and the third nanosheet N3 may be performed through an annealing process.

Particularly, referring to FIG. 16B, Ge may be diffused from the Ge layer 162 and introduced into the pre-first semiconductor layer P132. For example, Ge may be diffused from the Ge layer 162 in the first horizontal direction (the X direction) and introduced into the pre-first semiconductor layer P132. By the Ge diffusion, a Ge content ratio in the pre-first semiconductor layer P132 may increase, thereby forming the first semiconductor layer 132. The Ge content ratio in the first semiconductor layer 132 may be greater than or equal to 10 at % and less than 100 at %. In some embodiments, because Ge is diffused from the Ge layer 162 surrounding the sub-gate space GSS, the Ge content ratio in the first semiconductor layer 132 may gradually decrease as a distance to the Ge layer 162 increases.

Likewise, Ge may be diffused from the Ge layer 162 and introduced into the first nanosheet N1, the second nanosheet N2, and the third nanosheet N3. For example, Ge may be diffused from the Ge layer 162 in the vertical direction (Z direction) and/or the first horizontal direction (the X direction) and introduced into the first nanosheet N1, the second nanosheet N2, and the third nanosheet N3. By the Ge diffusion, a Ge content ratio in the first nanosheet N1, the second nanosheet N2, and the third nanosheet N3 may increase. In particular, a Ge content ratio in a portion of the first nanosheet N1, the second nanosheet N2, and the third nanosheet N3 adjacent to the Ge layer 162 may increase. Particularly, a Ge content ratio of the first portion N_P1 (see FIG. 6) of each of the first nanosheet N1, the second nanosheet N2, and the third nanosheet N3 adjacent to the Ge layer 162 may be greater than a Ge content ratio of the second portion N_P2 (see FIG. 6) separated from the Ge layer 162 with the first portion N_P1 therebetween. In some embodiments, because Ge is diffused from the Ge layer 162 surrounding the sub-gate space GSS, the Ge content ratio in the first nanosheet N1, the second nanosheet N2, and the third nanosheet N3 may gradually decrease as a distance to the Ge layer 162 increases.

In addition, Ge may be diffused from the Ge layer 162 and introduced into the fin-type active region FA.

In some embodiments, the annealing process for diffusing Ge is an in-situ process and may be performed at a temperature of 700° C. or less in a nitrogen (N₂) or hydrogen (H₂) environment.

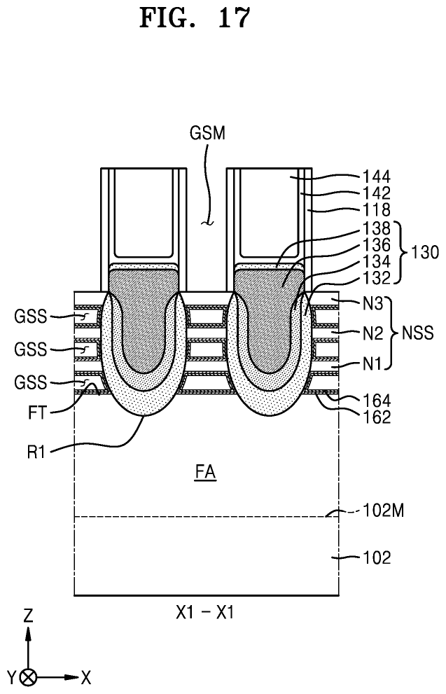

Referring to FIG. 17, the silicon capping layer 164 covering the Ge layer 162 may be formed inside the sub-gate space GSS. The silicon capping layer 164 may be separated from the first semiconductor layer 132, the plurality of nanosheet stacks NSS, and the fin top FT of the fin-type active region FA with the Ge layer 162 therebetween. The thickness of the silicon capping layer 164 may be in a range of about 0.5 nm to about 1 nm.

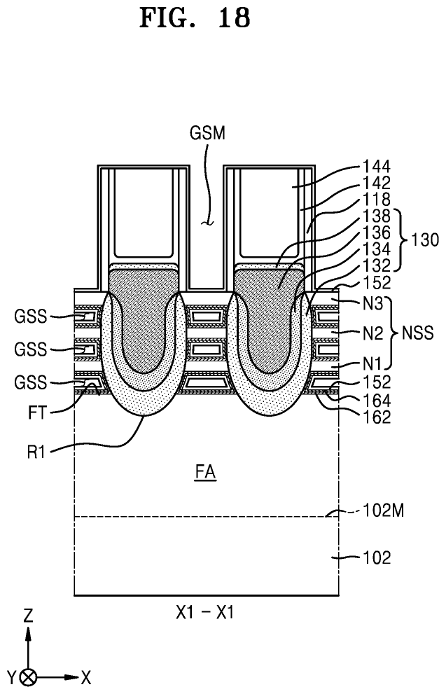

Referring to FIG. 18, the gate dielectric layer 152 may be formed in the main gate space GSM and the sub-gate space GSS. In the main gate space GSM, the gate dielectric layer 152 covering an exposed surface of the third nanosheet N3 may be formed. In the sub-gate space GSS, the gate dielectric layer 152 covering the silicon capping layer 164 may be formed. To form the gate dielectric layer 152, an atomic layer deposition (ALD) process may be used.

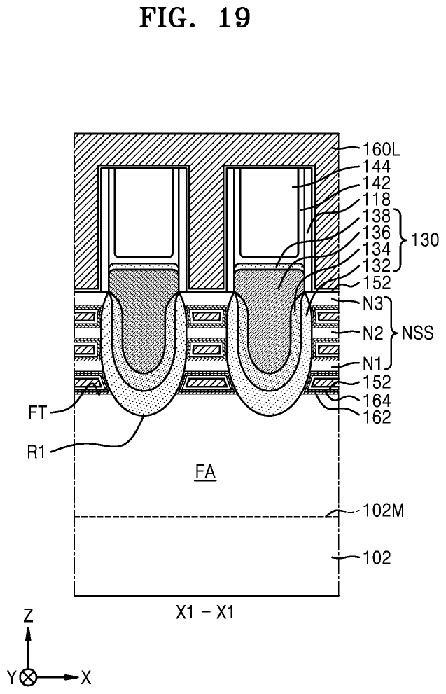

Referring to FIG. 19, from the result of FIG. 18, a gate-forming conductive layer 160L covering an upper surface of the inter-gate insulating layer 144 while filling the main gate space GSM and the sub-gate space GSS on the gate dielectric layer 152 may be formed. The gate-forming conductive layer 160L may include a metal, metal nitride, metal carbide, or a combination thereof. To form the gate-forming conductive layer 160L, an ALD or CVD process may be used.

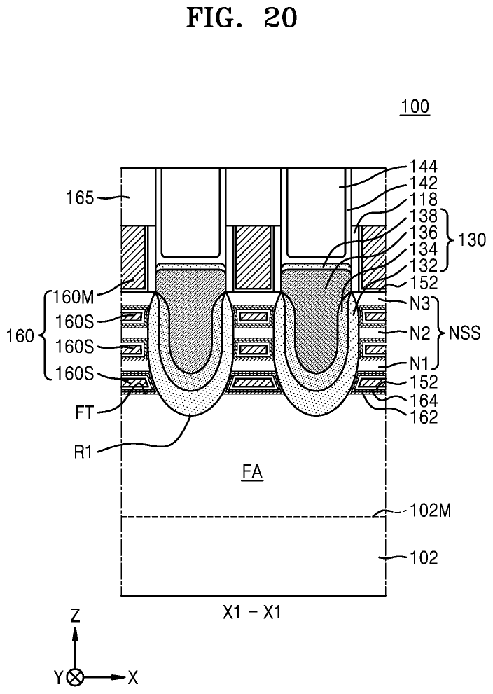

Referring to FIG. 20, from the result of FIG. 19, a portion of the gate-forming conductive layer 160L may be removed from an upper surface of the gate-forming conductive layer 160L so that the upper surface of the inter-gate insulating layer 144 is exposed and an upper portion of the main gate space GSM (see FIG. 18) is empty again. As a result, the plurality of gate lines 160 may be formed from the gate-forming conductive layer 160L. In this case, a portion of the gate dielectric layer 152 and a portion of the outer insulating spacer 118 may also be removed from upper sides thereof in the main gate space GSM, thereby decreasing the height of each of the gate dielectric layer 152 and the outer insulating spacer 118. Thereafter, the capping insulating pattern 165 filling the main gate space GSM on the gate line 160 may be formed.

Particularly, the main gate portion 160M may be formed in the main gate space GSM and the sub-gate portion 160S may be formed in the sub-gate space GSS (see FIG. 18). In particular, the sub-gate portion 160S surrounded by the silicon capping layer 164 and the Ge layer 162 in the sub-gate space GSS may be formed.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While the inventive concepts have been particularly shown and described with reference to example embodiments thereof, it will be understood that various changes in form and details may be made therein without departing from the scope of the following claims.

What is claimed is:

1. An integrated circuit device comprising:
a fin-type active region extending on a substrate in a first horizontal direction;
a channel region on the fin-type active region;
a gate line at least partially surrounding the channel region on the fin-type active region and extending in a second horizontal direction that intersects with the first horizontal direction; and
a source/drain region on the fin-type active region at a location adjacent to the gate line and in contact with the channel region,
wherein the source/drain region comprises a plurality of semiconductor layers, the plurality of semiconductor layers comprising:
a first semiconductor layer that comprises a portion in contact with the channel region and a portion in contact with the fin-type active region;
a second semiconductor layer on the first semiconductor layer; and
a third semiconductor layer on the second semiconductor layer,
wherein a germanium (Ge) content ratio in the first semiconductor layer is greater than or equal to 10 at % and less than 100 at %, and the Ge content ratio in the first semiconductor layer decreases towards a boundary with the second semiconductor layer.

2. The integrated circuit device of claim 1, wherein each of the first semiconductor layer, the second semiconductor layer, and the third semiconductor layer includes a silicon germanium (SiGe) layer doped with a p-type dopant.

3. The integrated circuit device of claim 1, wherein the Ge content ratio in the first semiconductor layer at the boundary with the second semiconductor layer is less than a Ge content ratio in the second semiconductor layer, and
wherein the Ge content ratio in the second semiconductor layer is less than a Ge content ratio in the third semiconductor layer.

4. The integrated circuit device of claim 1, wherein the gate line comprises a sub-gate portion that overlaps the first semiconductor layer in the first horizontal direction and a main gate portion that does not overlap the first semiconductor layer in the first horizontal direction,
wherein the first semiconductor layer comprises a protrusion portion that overlaps the sub-gate portion in the first horizontal direction, and
wherein, in the first semiconductor layer, a Ge content ratio in the protrusion portion is greater than a Ge content ratio in a portion other than the protrusion portion.

5. The integrated circuit device of claim 1, wherein the gate line comprises a sub-gate portion that overlaps the first semiconductor layer in the first horizontal direction and a main gate portion that does not overlap the first semiconductor layer in the first horizontal direction, and
wherein the integrated circuit device further comprises a Ge layer that at least partially surrounds the sub-gate portion.

6. The integrated circuit device of claim 1, wherein the Ge content ratio in the first semiconductor layer decreases from a maximum content ratio that is less than 100 at % to a first content ratio that is greater than or equal to 10 at % towards the boundary with the second semiconductor layer.

7. An integrated circuit device comprising:
a fin-type active region extending on a substrate in a first horizontal direction;
a nanosheet facing a fin top of the fin-type active region at a location separated from the fin top of the fin-type active region;
a gate line at least partially surrounding the nanosheet on the fin-type active region and extending longitudinally in a second horizontal direction that intersects with the first horizontal direction; and
a source/drain region facing the nanosheet in the first horizontal direction,
wherein the source/drain region comprises a plurality of semiconductor layers, the plurality of semiconductor layers comprising:
a first semiconductor layer that comprises a portion in contact with the nanosheet and a portion in contact with the fin-type active region;
a second semiconductor layer on the first semiconductor layer; and
a third semiconductor layer on the second semiconductor layer,
wherein a germanium (Ge) content ratio in the first semiconductor layer is greater than or equal to 10 at % and less than 100 at %,
wherein the Ge content ratio in the first semiconductor layer decreases towards a boundary with the second semiconductor layer,
wherein the nanosheet comprises a first portion adjacent to the gate line and a second portion separated from the gate line with the first portion therebetween, and a Ge content ratio in the first portion is greater than a Ge content ratio in the second portion.

8. The integrated circuit device of claim 7, wherein each of the first semiconductor layer, the second semiconductor layer, and the third semiconductor layer includes a silicon germanium (SiGe) layer doped with a p-type dopant.

9. The integrated circuit device of claim 7, wherein the Ge content ratio in the first semiconductor layer at the boundary with the second semiconductor layer is less than a Ge content ratio in the second semiconductor layer, and
wherein the Ge content ratio in the second semiconductor layer is less than a Ge content ratio in the third semiconductor layer.

10. The integrated circuit device of claim 7, wherein a Ge content ratio in the nanosheet increases towards the gate line.

11. The integrated circuit device of claim 7, wherein the gate line comprises a sub-gate portion that overlaps the first semiconductor layer in the first horizontal direction and a main gate portion that does not overlap the first semiconductor layer in the first horizontal direction,
wherein the integrated circuit device further comprises a Ge layer that at least partially surrounds the sub-gate portion, and
wherein a thickness of the Ge layer is 1 nm or less.

12. The integrated circuit device of claim 11, further comprising a silicon capping layer between the Ge layer and the sub-gate portion, wherein a thickness of the silicon capping layer is in a range of about 0.5 nm to about 1 nm.

13. The integrated circuit device of claim 12, further comprising a gate dielectric layer between the silicon capping layer and the sub-gate portion.

14. The integrated circuit device of claim 7, wherein the Ge content ratio in the first semiconductor layer decreases from a maximum content ratio that is less than 100 at % to a first content ratio that is greater than or equal to 10 at % towards the boundary with the second semiconductor layer.

15. The integrated circuit device of claim 14, wherein the Ge content ratio in the first semiconductor layer has the first content ratio at the boundary with the second semiconductor layer.

16. The integrated circuit device of claim 15, wherein the second semiconductor layer comprises a portion having a second content ratio of Ge that is greater than the first content ratio, and
wherein the third semiconductor layer comprises a portion having a third content ratio of Ge that is greater than the second content ratio.

17. An integrated circuit device comprising:
a fin-type active region extending on a substrate in a first horizontal direction;
a plurality of nanosheets facing a fin top of the fin-type active region at respective locations that are separated from the fin top and having different respective distances from the fin top in a vertical direction;
a gate line at least partially surrounding each of the plurality of nanosheets on the fin-type active region and extending longitudinally in a second horizontal direction that intersects with the first horizontal direction; and
a source/drain region facing the plurality of nanosheets in the first horizontal direction,
wherein the source/drain region comprises a plurality of semiconductor layers, the plurality of semiconductor layers comprising:
a first semiconductor layer that includes a portion in contact with the plurality of nanosheets and a portion in contact with the fin-type active region;
a second semiconductor layer on the first semiconductor layer; and
a third semiconductor layer on the second semiconductor layer,
wherein each of the first semiconductor layer, the second semiconductor layer, and the third semiconductor layer includes a silicon germanium (SiGe) layer doped with a p-type dopant,
wherein a germanium (Ge) content ratio in the first semiconductor layer is greater than or equal to 10 at % and less than 100 at %,
wherein the Ge content ratio in the first semiconductor layer decreases towards a boundary with the second semiconductor layer,
wherein the gate line comprises a sub-gate portion that overlaps the first semiconductor layer in the first horizontal direction and a main gate portion that does not overlap the first semiconductor layer in the first horizontal direction, and
wherein the Ge content ratio in the first semiconductor layer increases towards the sub-gate portion.

18. The integrated circuit device of claim 17, wherein the Ge content ratio in the first semiconductor layer at the boundary with the second semiconductor layer is less than a Ge content ratio in the second semiconductor layer, and
wherein the Ge content ratio in the second semiconductor layer is less than a Ge content ratio in the third semiconductor layer.

19. The integrated circuit device of claim 17, wherein the source/drain region is a first source/drain region,
wherein the integrated circuit device further comprises a second source/drain region spaced apart from the first source/drain region with the gate line and the plurality of nanosheets therebetween, and
wherein the first and second source/drain regions, the gate line, and the plurality of nanosheets constitute a positive channel metal oxide semiconductor (PMOS) transistor.

20. The integrated circuit device of claim 17, further comprising:
a Ge layer that at least partially surrounds the sub-gate portion; and
a silicon capping layer between the Ge layer and the sub-gate portion,
wherein a thickness of the Ge layer is 1 nm or less and a thickness of the silicon capping layer is in a range of about 0.5 nm to about 1 nm.
